(19) United States
(12) Patent Application Publication
(10) Pub. No.: US 2025/0141433 A1
(43) Pub. Date: May 1, 2025

(54) Forgetful Bloom Filter Structure

(71) Applicant: Arm Limited, Cambridge (GB)

(72) Inventors: Michael Bartling, Austin, TX (US); Brendan James Moran, Coton (GB)

(21) Appl. No.: 18/497,733

(22) Filed: Oct. 30, 2023

(51) Int. Cl. H03H 21/00

(52) U.S. Cl. CPC H03H 21/0043; H03H 2021/005

(57) ABSTRACT

Various implementations described herein are directed to a device having a write circuit that provides data for storage. The device may include a memory circuit that stores the data in leaky bitcells with capacitive elements that gradually discharge over a pre-determined period of time. The device may include a read circuit that enables the leaky bitcells to operate as one or more memory storage elements. The device may include a query circuit that identifies matches between a query data and output data provided by the read circuit.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In some modern circuit architectures, bloom filters are configured to perform an Approximate Membership Query (AMQ). One feature is that a bloom filter allows a simple check as to whether an element is a member of a data set that is described by the bloom filter. In such an instance, the AMQ returns one of two results: either a) definitely NOT in the data set, or b) maybe in the data set. However, some operations on bloom filters are typically difficult and somewhat complex to implement. For instance, once a member is committed to the data set, it can be substantially difficult to remove the added member from the data set without rebuilding the entire data set, or without maintaining substantial overhead when managing access history of the data set. As such, this can complicate the construction of adaptive structures that filter only for recent elements. Although some progress has been made to enable the counting of bloom filters, this typically requires the addition of a counter for each bit, which can complicate the bloom filter and reduce its desirability as an AMQ algorithm, especially for physical implementations in some modern computing systems. As such, there exists a need for an efficient bloom filter design that improves integration schemes and techniques to thereby enhance performance of bloom filters and related circuitry by providing efficient and effective bitcell design schemes and techniques for various memory based bloom filter applications.

### BRIEF DESCRIPTION OF THE DRAWINGS

Implementations of various techniques are described herein with reference to the drawings. It should be understood that the drawings illustrate various implementations described herein and are not meant to limit the embodiments described herein.

FIGS. 1A-1C illustrate various diagrams associated with a bitcell structure in a first configuration in accordance with various implementations described herein.

FIG. 2 illustrates a diagram of a forgetful memory array (FMA) structure in accordance with various implementations described herein.

FIG. 3 illustrates a diagram of a forgetful bloom filter core in accordance with various implementations described herein.

FIG. 4 illustrates a diagram of a forgetful bloom filter core in accordance with various implementations described herein.

FIGS. 5A-5C illustrate various diagrams associated with a bitcell structure in a second configuration in accordance with various implementations described herein.

FIG. 6 illustrates a diagram of a forgetful memory array (FMA) structure in accordance with various implementations described herein.

FIG. 7 illustrates a diagram of a forgetful bloom filter core with refresh in accordance with various implementations described herein.

FIG. 8 illustrates a process diagram associated with the bitcell structure in the various configurations in accordance with various implementations described herein.

FIG. 9 illustrates a diagram of match output architecture in accordance with various implementations described herein.

FIGS. 10A-10C illustrate various diagrams associated with a bitcell structure in a third configuration in accordance with various implementations described herein.

FIG. 11 illustrates a schematic diagram of a destructive read bitcell structure in accordance with various implementations described herein.

### DETAILED DESCRIPTION

Various implementations described herein are directed to forgetful bloom filter schemes and techniques for memory applications in various circuit related designs. Also, in some implementations, forgetful bloom filter schemes and techniques described herein compensate for the lack of forgetfulness in a bloom filter by changing how the bloom filter itself is stored. As such, various forgetful bloom filter schemes and techniques described herein provide a capacitive storage element that is ground-referenced, or in some cases, positive-supply-voltage-referenced. For instance, as the capacitive storage element leaks to ground, the capacitive storage element slowly decays or discharges, and any ‘1’ bits gradually reduce to ‘0’. In this way, the bloom filter “forgets” over time.

In general, this leaky discharge technique cannot be implemented using DRAM cells because reads are destructive in DRAM cells. One reason for using a non-DRAM implementation is that failed matches should not cause a refresh. Also, because DRAM reads are destructive, they must be accompanied by a corresponding rewrite; however, in some cases, a rewrite operation may cause an undesired refresh.

Therefore, the various forgetful bloom filter schemes and techniques described herein utilize a memory element circuit that stores the data in leaky bitcells with capacitive elements that gradually discharge over a pre-determined period of time.

Various implementations of forgetful bloom filter schemes and techniques for memory based applications will now be described herein in reference to the drawings.

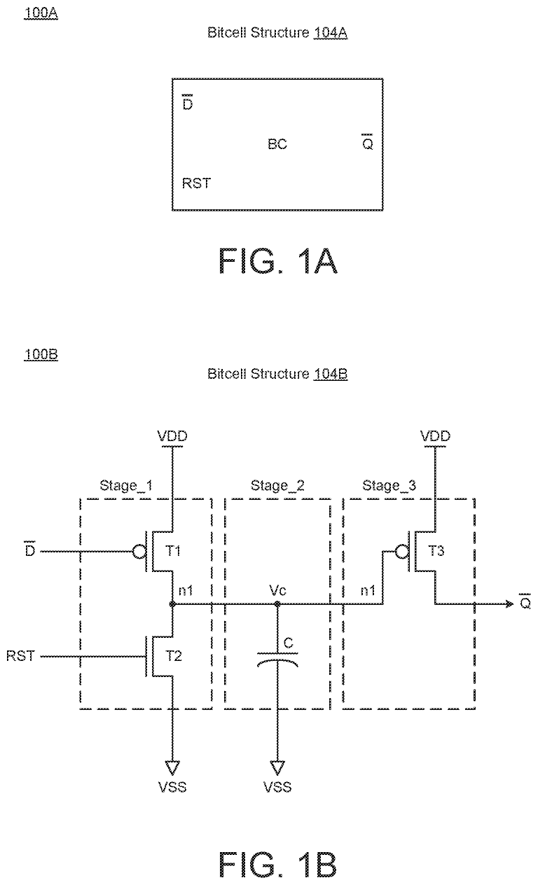

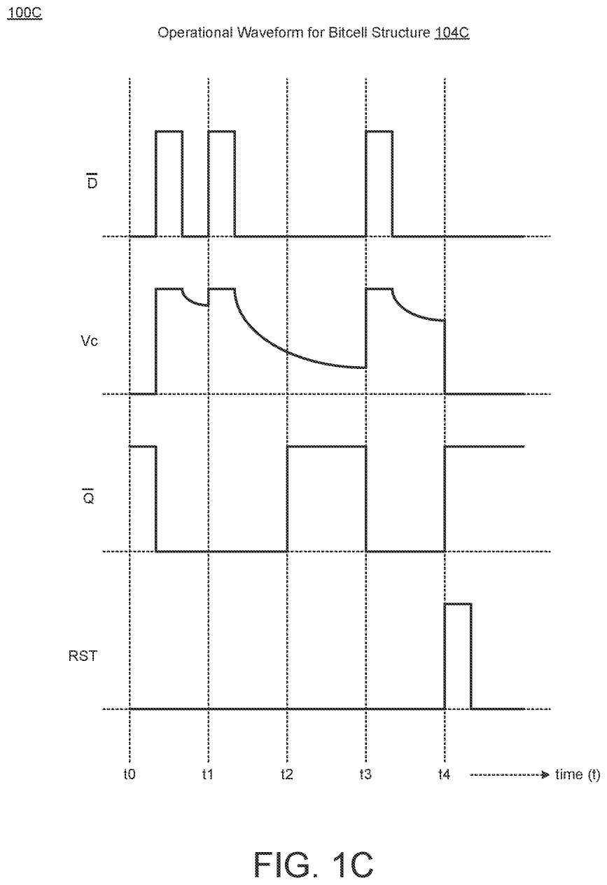

FIGS. 1A-1C illustrate various diagrams associated with a bitcell structure in a first configuration in accordance with implementations as described herein. In particular, FIG. 1A shows a high-level conceptual diagram 100A of a bitcell structure 104A in the first configuration, FIG. 1B shows a transistor-level diagram 100B of a bitcell structure 104B in the first configuration, and also, FIG. 1C shows an operational waveform diagram 100C for the bitcell structure 104C in the first configuration.

In various implementations, the bitcell architecture may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the bitcell architecture as an integrated device may involve the use of various circuit components and/or related structures described herein so as to implement various techniques associated therewith. Also, the bitcell architecture may be integrated with various circuitry and/or related components on a single chip, and also, the bitcell architecture may be implemented in various embedded devices for use in automotive, mobile, computer, server and/or Internet-of-Things (IoT) based applications, including various circuits related thereto, such as, e.g., remote sensor nodes.

As shown in FIG. 1A, the bitcell architecture 104A may be implemented as a forgetful memory device having a leaky bitcell (BC) with at least one capacitive element, such as, e.g., a capacitor (C). Also, the bitcell architecture 104A may include one or more inputs, such as, e.g., input data (D) and reset (RST), and at least one output, such as, e.g., output data (Q). In some applications, the input data (D) may refer to inverted input data (D-not), and also, the output data may refer to inverted output data (Q-not).

As shown in FIG. 1B, the bitcell architecture 104B may have multiple stages, including a first stage (Stage_1), a second stage (Stage_2), and a third stage (Stage_3), that are arranged and coupled together in a first configuration so as to thereby operate as the forgetful memory device (e.g., as shown in FIG. 1A) having a leaky bitcell (BC) with at least one capacitive element, such as, e.g., a capacitor (C).

In some implementations, the first stage (Stage_1) may refer to a write element or write circuit stage of the leaky bitcell, wherein the write circuit stage (Stage_1) provides data for storage in the second stage (Stage_2). Also, in some applications, the first stage (Stage_1) may include one or more transistors, such as, e.g., transistors (T1, T2) coupled together in series between a supply voltage (VDD) and ground (VSS or GND). As shown, transistor (T1) is coupled between the supply voltage (VDD) and node (n1), and transistor (T2) is coupled between node (n1) and ground (VSS or GND). Also, input data (D-not) is coupled to the gate of transistor (T1), and also, input reset (RST) is coupled to the gate of transistor (T2). Also, transistor (T1) may be a P-type transistor, and transistor (T2) may be an N-type transistor; however, other configurations may be used.

In some implementations, the second stage (Stage_2) may refer to a memory element or memory circuit stage of the leaky bitcell, wherein the memory circuit stage (Stage_2) stores the data received from the first stage (Stage_1) in at least one capacitive element, such as, e.g., the capacitor (C), that gradually discharges over a pre-determined period of time. Also, in various applications, the capacitor (C) may have a decay time that is determined by the size of the capacitor (C), self-leakage current of the capacitor (C), and/or leakage current of connected transistors, such as, e.g., one or more of transistors (T1, T2, T3). As such, the leaky bitcell may be referred to as a capacitive bitcell having the capacitive element, such as, e.g., the capacitor (C), that gradually discharges over the period of time by slowly leaking stored charge over the period of time. Also, the capacitor (C) may be coupled between node (n1) or node (Vc) and ground (VSS or GND), wherein node (Vc) refers to the voltage potential of the capacitor (C) at node (n1).

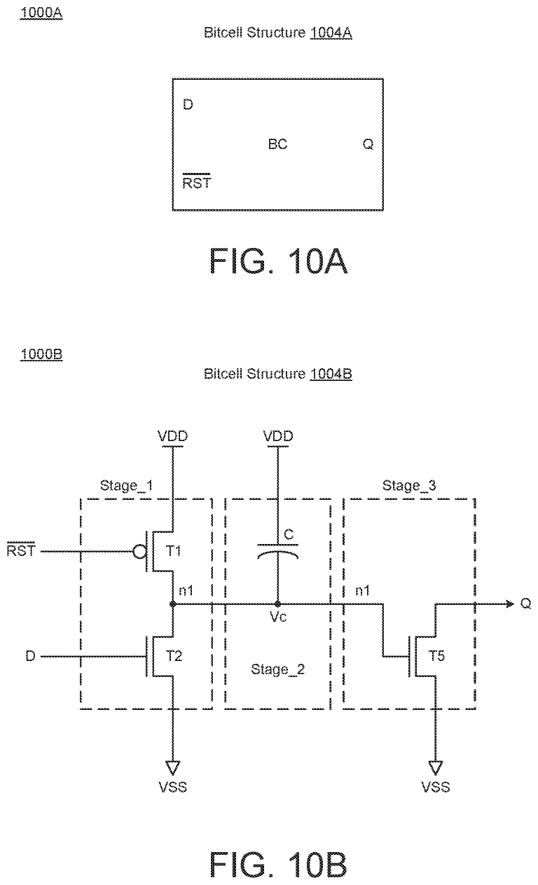

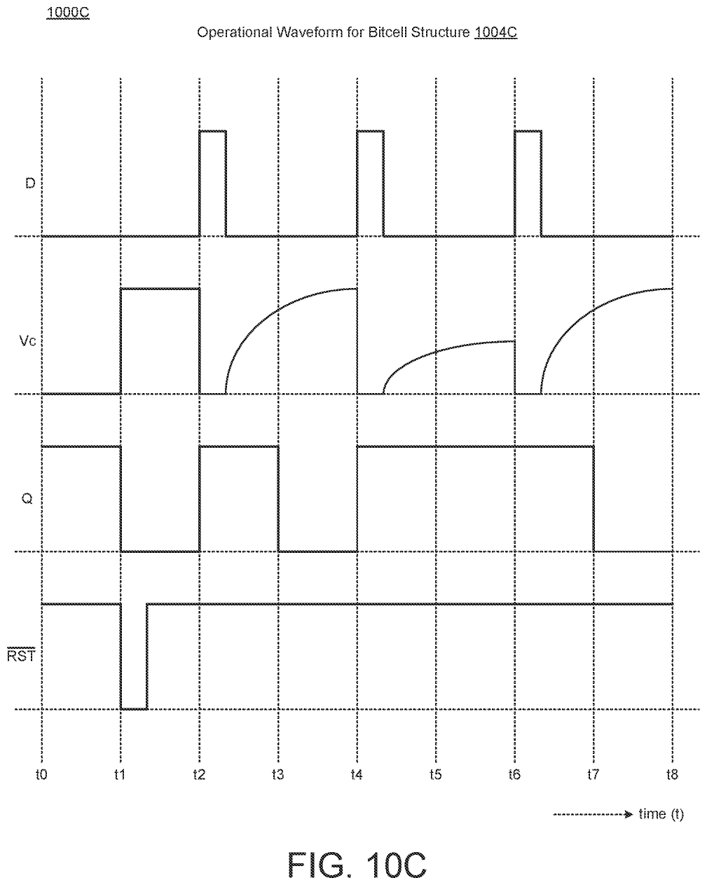

In some instances, the capacitive element or capacitor (C) may be referenced to ground (VSS or GND) such that the capacitive element or capacitor (C) slowly leaks to ground (VSS or GND) so that the leaky bitcell is configured to forget its data storage value over the period of time. Also, in other instances, as shown in FIG. 10B, the capacitive element or capacitor (C) may be referenced to a supply voltage (VDD) such that the capacitive element or capacitor (C) slowly leaks to the supply voltage (VDD) so that the leaky bitcell is configured to forget its data storage value over the period of time. Thus, in various instances, the leaky bitcell may be provided with a capacitive storage element that is ground-referenced (VSS or GND) or that is supply-voltage-referenced (VDD), which corresponds to a positive voltage supply (VDD).

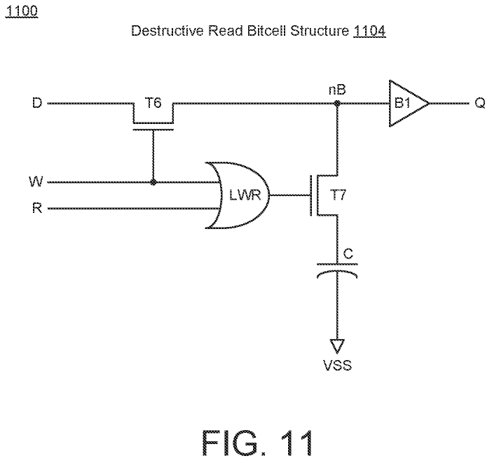

In some implementations, the third stage (Stage_3) may refer to a read element or a read circuit stage of the leaky bitcell, wherein the read circuit stage (Stage_3) enables the leaky bitcell to operate as one or more memory storage elements. In some instances, the read element may refer to a non-destructive read element of the leaky bitcell, wherein the non-destructive read circuit enables the leaky bitcell to operate as a non-destructive memory storage element without need for destructive read operations that cause a refresh operation. Moreover, in some other instances, the read element may refer to a destructive read element, as described in reference to the bitcell structure 1104 in FIG. 11.

Also, in some applications, the third stage (Stage_3) may include one or more transistors, such as, e.g., transistor (T3) that is coupled between the supply voltage (VDD) and output node (Q-not). As shown, the output of transistor (T1) is coupled to the gate of transistor (T3) at node (n1), and also, the output of transistor (T3) is coupled to the output node (Q-not). In some instances, transistor (T3) may be a P-type transistor; however, in other instances, other configurations may be used to achieve similar results.

As shown in FIG. 1C, the operational waveform diagram 100C for the bitcell structure 104A, 104B in the first configuration shows the input data signal (D-not), the Vc signal at node (n1), the output data signal (Q-not), and the reset signal (RST). As shown, in time period (t0-t1), the input data signal (D-not) triggers the Vc signal at node (n1) and the output signal (Q-not) inverts low, when the reset signal (RST) is deactivated, wherein the Vc signal slowly decays or discharges to time (t1). As such, when the input data signal (D-not) is high, the Vc signal triggers high followed by slow decay or discharge, and the output signal (Q-not) is low.

Also, in time period (t1-t2), the input data signal (D-not) triggers the Vc signal high at node (n1) and the output signal (Q-not) inverts from low to high at time (t2), when the reset signal (RST) is deactivated, wherein the Vc signal slowly decays or discharges to time (t3). Also, in time period (t2-t3), the input data signal (D-not) is low, while the Vc signal at node (n1) slowly decays or discharges to time (t3), and the output signal (Q-not) remains high during the slow decay or discharge of the Vc signal to time (t3).

Also, in time period (t3-t4), the input data signal (D-not) triggers the Vc signal high at node (n1) and the output signal (Q-not) inverts from high to low at time (t3), when the reset signal (RST) is deactivated, wherein the Vc signal slowly decays or discharges to time (t4). Also, at time (t4 and >t4), upon activation and/or triggering of the reset signal (RST) from low to high, the input data signal (D-not) is low, the Vc signal at node (n1) falls to low, and the output signal (Q-not) rises from low to high.

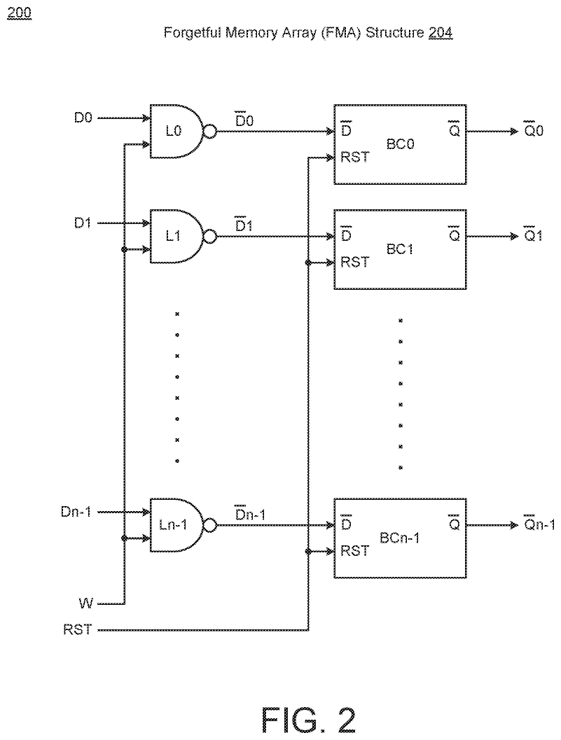

FIG. 2 illustrates a schematic layout diagram 200 of a forgetful memory array (FMA) structure 204 in accordance with various implementations described herein.

In various implementations, the FMA structure 204 may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the FMA structure 204 as an integrated device may involve the use of various circuit components and/or related structures described herein so as to implement various techniques associated therewith. Also, the FMA structure 204 may be integrated with various circuitry and/or related components on a single chip, and also, the FMA structure 204 may be implemented in various embedded devices for use in automotive, mobile, computer, server and/or Internet-of-Things (IoT) based applications, including various circuits related thereto, such as, e.g., remote sensor nodes.

As shown in FIG. 2, the forgetful memory array (FMA) structure 204 may be implemented as a forgetful bloom filter having an array of leaky bitcells (BC0, BC1, . . . , BCn−1) with each leaky bitcell having at least one capacitive element, such as at least one capacitor (C), in a manner as shown in FIG. 1B. As such, the forgetful memory array (FMA) structure 204 may be implemented as a forgetful bloom filter with the one or more leaky bitcells as forgetful memory cells comprising capacitive elements (C) that gradually discharge over a period of time. Also, FMA structure 204 may include one or more inputs, such as, e.g., input data (D0, D1, . . . , Dn−1), write enable input (W) and reset input (RST), along with output data (Q0, Q1, . . . , Qn−1). In some applications, the output data (Q0, Q1, . . . , Qn−1) may refer to inverted output data (Q0-not, Q1-not, . . . , Qn−1-not).

In some implementations, the FMA structure 204 may include logic gates, such as, e.g., NAND logic gates (L0, L1, Ln−1), that receive the input data (D0, D1, . . . , Dn−1), receive the write enable input (W), and then provide inverted input data (D0-not, D1-not, . . . , Dn−1-not) to corresponding leaky bitcells (BC0, BC1, . . . , BCn−1). For instance, each NAND logic gate (L0, L1, Ln−1) receives corresponding input data (D0, D1, . . . , Dn−1), receives the write enable input (W), and then provides corresponding inverted input data (D0-not, D1-not, . . . , Dn−1-not) to corresponding leaky bitcells (BC0, BC1, . . . , BCn−1) in the forgetful memory array (FMA) structure 204. Also, each corresponding leaky bitcell (BC0, BC1, . . . , BCn−1) receives corresponding inverted input data (D0-not, D1-not, . . . , Dn−1-not), receives the reset input (RST), and provides corresponding inverted output data (Q0-not, Q1-not, . . . , Qn−1-not), as output from the FMA structure 204.

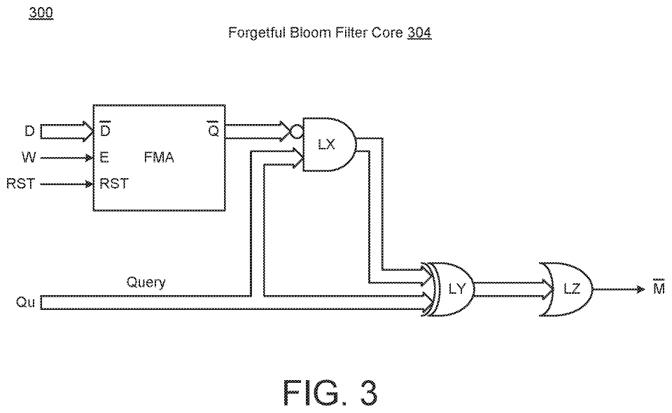

FIG. 3 illustrates a schematic diagram 300 of a forgetful bloom filter core 304 in accordance with various implementations described herein.

In various implementations, the forgetful bloom filter core 304 may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the forgetful bloom filter core 304 as an integrated device may involve use of various circuit components and/or related structures described herein so as to implement various techniques associated therewith. Also, the forgetful bloom filter core 304 may be integrated with various circuitry and/or related components on a single chip, and the forgetful bloom filter core 304 may be implemented in various embedded devices for use in automotive, mobile, computer, server and/or IoT based applications, including, e.g., remote sensor nodes.

As shown in FIG. 3, the forgetful bloom filter core 304 may be implemented with the forgetful memory array (FMA) structure 204 in FIG. 2 having the array of leaky bitcells (BC0, BC1, . . . , BCn−1), wherein each leaky bitcell has at least one capacitive element, such as at least one capacitor (C), in a manner as shown in FIG. 1B. As such, the forgetful bloom filter core 304 may be implemented as a forgetful bloom filter with the array of leaky bitcells as an array of forgetful memory cells comprising capacitive elements (C) that gradually discharge over a period of time. Also, the forgetful bloom filter core 304 may include one or more inputs, such as, e.g., input data (D: D0, D1, . . . , Dn−1), the write enable input (W coupled to E), and the reset input (RST), along with the output data (Q-not: Q0-not, Q1-not, . . . , Qn−1-not).

In some implementations, the forgetful bloom filter core 304 may include multi-input logic gates, such as, e.g., AND gate (LX), XOR gate (LY), and OR gate (LZ). For instance, the AND gate (LX) may receive the output data (Q-not: Q0-not, Q1-not, . . . , Qn−1-not) at an inverting input, receive a query input (Qu) at a non-inverting input, and provide output to the XOR gate (LY). Also, the XOR gate (LY) may receive the output from the AND gate (LX), receive the query input (Qu), and provide output to the OR gate (LZ). Also, the OR gate (LZ) may receive the output from the XOR gate (LY), and provide a match output (M-not) as output from the forgetful bloom filter core 304. In some applications, the logic gates (LX, LY, LZ) refer to a query circuit that identifies matches between a query data (input Qu) and the output data (Q-not: Q0-not, Q1-not, . . . , Qn−1-not) provided by the read element(s) or the read circuit stage(s) of the forgetful bloom filter core 304.

In some applications, upon receiving the query input (Qu), the query circuit (LX, LY, LZ) may invert data bits of the output data (Q-not) and then mask the inverted data bits of the output data (Q-not) so as to isolate the inverted data bits of the output data (Q-not) having a high logic state. After isolating the inverted data bits, the query circuit (LX, Ly, LZ) may XOR (e.g., with LY) the masked inverted data bits with data bits of the query input (Qu) to generate queried output data. If there is a match between data bits of stored input data and data bits of the queried output data, then the query circuit (LX, LY, LZ) may assert a match signal (M-not). Otherwise, if there is a mismatch between the data bits of the stored input data and the data bits of the queried output data, then the query circuit (LX, LY, LZ) may be configured to assert a mismatch signal with the M signal.

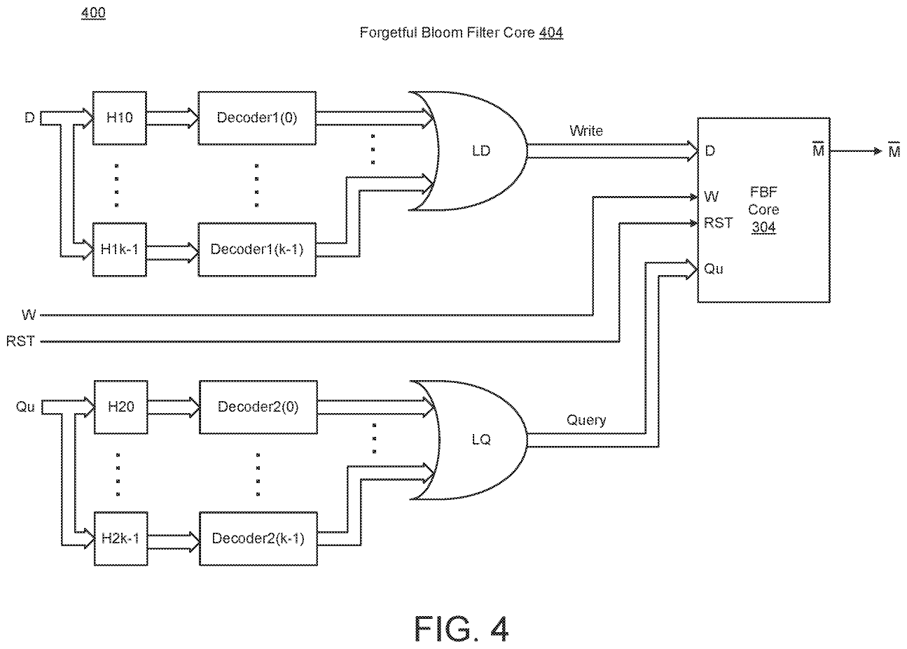

FIG. 4 illustrates a diagram 400 of a forgetful bloom filter core 404 with hash function in accordance with various implementations described herein.

As shown in FIG. 4, the forgetful bloom filter core 404 may be implemented with the forgetful bloom filter (FBF) core 304 of FIG. 3 along with a data hash circuit for write operations and a query hash circuit for query operations. In some applications, the data hash circuit has hash function blocks (H10, . . . , H1k−1) that receive data input (D) and then provides hashed data input to corresponding decoder blocks (Decoder1(0), . . . , Decoder1(k−1)), which then provides decoded hashed data to logic device (LD), such as, e.g., an OR gate, that then provides write data to the D-input of the FBF core 304. Also, in some applications, the query hash circuit has hash function blocks (H20, . . . , H2k−1) that receives query input (Q) and provides hashed query input to corresponding decoder blocks (Decoder2(0), . . . , Decoder2(k−1)), which then provides decoded hashed query input to logic device (LQ), such as, e.g., an OR gate, that then provides the query data to the Qu-input of the FBF core 304. Also, the forgetful bloom filter core 404 includes other inputs, such as, e.g., write enable (W) and reset (RST), and the forgetful bloom filter core 404 includes at least one output, including, e.g., the match output (M-not).

In some implementations, the data-query hash functions (H10, . . . , H1k−1 and H20, . . . , H2k−1) may be configured to write data bits or query data bits in the leaky bitcells of the FBF core 304. In various applications, hash functions are important to bloom filters, and examples of hash functions may include, but not limited to, non-cryptographic hash functions. Also, various other examples of hash functions may include one or more of the following, including, e.g., CRC, FNV1 and SHA. The hash functions may also be used to implement various logic based filters, including, e.g., an XOR filter.

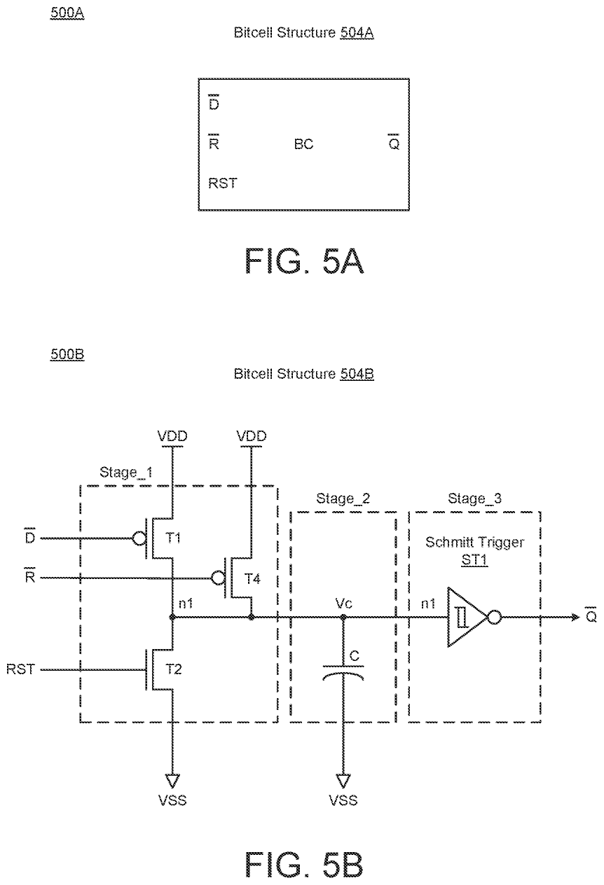

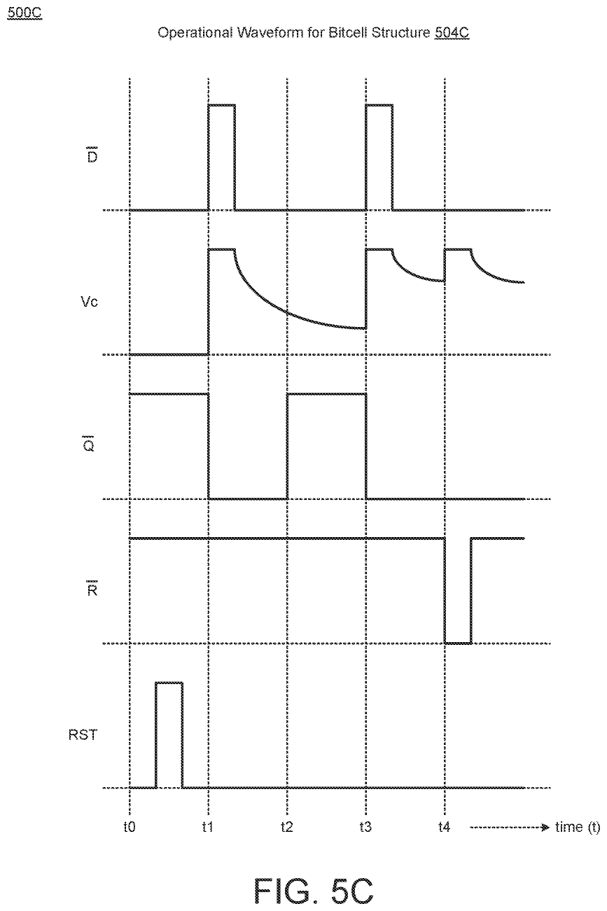

FIGS. 5A-5C illustrate various diagrams associated with a bitcell structure in a second configuration in accordance with various implementations described herein. In particular, FIG. 5A shows a high-level conceptual diagram 500A of a bitcell structure 504A in the second configuration, FIG. 5B shows a transistor-level diagram 500B of a bitcell structure 504B in the second configuration, and FIG. 5C shows an operational waveform diagram 500C for the bitcell structure 504C in the second configuration.

In various implementations, the bitcell architecture may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the bitcell architecture as an integrated device may involve the use of various circuit components and/or related structures described herein so as to implement various techniques associated therewith. Also, the bitcell architecture may be integrated with various circuitry and/or related components on a single chip, and also, the bitcell architecture may be implemented in various embedded devices for use in automotive, mobile, computer, server and/or Internet-of-Things (IoT) based applications, including various circuits related thereto, such as, e.g., remote sensor nodes.

As shown in FIG. 5A, the bitcell architecture 504A may be implemented as a forgetful memory device having a leaky bitcell (BC) with at least one capacitive element, such as, e.g., a capacitor (C). Also, the bitcell architecture 504A may include one or more inputs, such as, e.g., input data (D), refresh (R) and reset (RST), and at least one output, such as, e.g., output data (Q). In various applications, the input data (D) refers to inverted input data (D-not), refresh (R) refers to inverted refresh (R-not) and also, the output data may refer to inverted output data (Q-not).

As shown in FIG. 5B, the bitcell architecture 504B may have multiple stages, including a first stage (Stage_1), a second stage (Stage_2), and a third stage (Stage_3), that are arranged and coupled together in a second configuration so as to thereby operate as the forgetful memory device (e.g., as shown in FIG. 5A) having a leaky bitcell (BC) with at least one capacitive element, such as, e.g., a capacitor (C).

In some implementations, the first stage (Stage_1) may refer to a write element or write circuit stage of the leaky bitcell, wherein the write circuit stage (Stage_1) provides data for storage in the second stage (Stage_2). Also, in some applications, the first stage (Stage_1) may include one or more transistors, such as, e.g., transistors (T1, T2, T4) coupled together in series between supply voltage (VDD) and ground (VSS or GND). As shown, transistor (T1) is coupled between the supply voltage (VDD) and node (n1), and transistor (T2) is coupled between node (n1) and ground (VSS or GND). Also, transistor (T4) is coupled between the supply voltage (VDD) and node (n1). Also, input data (D-not) is coupled to the gate of transistor (T1), refresh (R-not) is coupled to the gate of transistor (T4), and also, input reset (RST) is coupled to the gate of transistor (T2). Also, transistors (T1, T4) may be P-type transistors, and also, transistor (T2) may be an N-type transistor; however, various other configurations may be used.

In some implementations, the second stage (Stage_2) may refer to a memory element or memory circuit stage of the leaky bitcell, wherein the memory circuit stage (Stage_2) stores the data received from the first stage (Stage_1) in at least one capacitive element, such as, e.g., the capacitor (C), that gradually discharges over a pre-determined period of time. Also, in various applications, the capacitor (C) may have a decay time that is determined by the size of the capacitor (C), self-leakage current of the capacitor (C), and/or leakage current of connected transistors, such as, e.g., one or more of transistors (T1, T2, T4). As such, the leaky bitcell may be referred to as a capacitive bitcell having the capacitive element, such as, e.g., the capacitor (C), that gradually discharges over the period of time by slowly leaking stored charge over the period of time. Also, the capacitor (C) may be coupled between node (n1) or node (Vc) and ground (VSS or GND), wherein node (Vc) refers to the voltage potential of the capacitor (C) at node (n1).

In some instances, the capacitive element or capacitor (C) may be referenced to ground (VSS or GND) such that the capacitive element or capacitor (C) slowly leaks to ground (VSS or GND) so that the leaky bitcell is configured to forget its data storage value over the period of time. Also, in other instances, as shown in FIG. 10B, the capacitive element or capacitor (C) may be referenced to a supply voltage (VDD) such that the capacitive element or capacitor (C) slowly leaks to the supply voltage (VDD) so that the leaky bitcell is configured to forget its data storage value over the period of time. Thus, in various instances, the leaky bitcell may be provided with a capacitive storage element that is ground-referenced (VSS or GND) or that is supply-voltage-referenced (VDD), which corresponds to a positive voltage supply (VDD).

In some implementations, the third stage (Stage_3) may refer to a read element or a read circuit stage of the leaky bitcell, wherein the read circuit stage (Stage_3) enables the leaky bitcell to operate as one or more memory storage elements. In some instances, the read element may refer to a non-destructive read element of the leaky bitcell, wherein the non-destructive read circuit enables the leaky bitcell to operate as a non-destructive memory storage element. In other instances, the read element may refer to a destructive read element, as described in reference to the bitcell structure 1104 in FIG. 11.

Also, in some applications, the third stage (Stage_3) may include a Schmitt trigger (ST1) that is coupled between node (n1) and output node (Q-not). Thus, the input of the Schmitt trigger (ST1) is coupled to node (n1), and the output of the Schmitt trigger (ST1) is coupled to the output node (Q-not). Accordingly, non-destructive read element, circuit and/or stage (Stage_3) may be implemented with a Schmitt trigger.

As shown in FIG. 5C, the operational waveform diagram 500C for the bitcell structure 504A, 504B in the second configuration shows the input data signal (D-not), the Vc signal at node (n1), the output data signal (Q-not), the refresh signal (R-not), and the reset signal (RST). As shown, in time period (t0-t1), during activation of the reset signal (RST) high, the input data signal (D-not) is low, the Vc signal at node (n1) is low, the output data signal (Q-not) is high, the refresh signal (R-not) is high.

Also, in time period (t1-t2), the input data signal (D-not) triggers the Vc signal at node (n1) high and the output signal (Q-not) inverts low, when the reset signal (RST) is deactivated, wherein the Vc signal slowly decays or discharges to time (t2 and t3). As such, when the input data signal (D-not) is high, the Vc signal triggers high followed by slow decay or discharge, and the output signal (Q-not) is low. Also, in time period (t2-t3), the input data signal (D-not) is low, while the Vc signal at node (n1) continues to slowly decay or discharge to time (13), and the output signal (Q-not) inverts high during the slow decay or discharge of the Vc signal from time (t2) to time (t3).

Also, in time period (t3-t4), the input data signal (D-not) triggers the Vc signal high at node (n1) and the output signal (Q-not) inverts from high to low at time (t3), while the reset signal (RST) is deactivated, wherein the Vc signal slowly decays or discharges to time (t4). Also, at time (t4 and >t4), refresh (R-not low) is activated, and the input data signal (D-not) is low, the Vc signal at node (n1) rises to high followed by slow decay or discharge, and the output signal (Q-not) remains low.

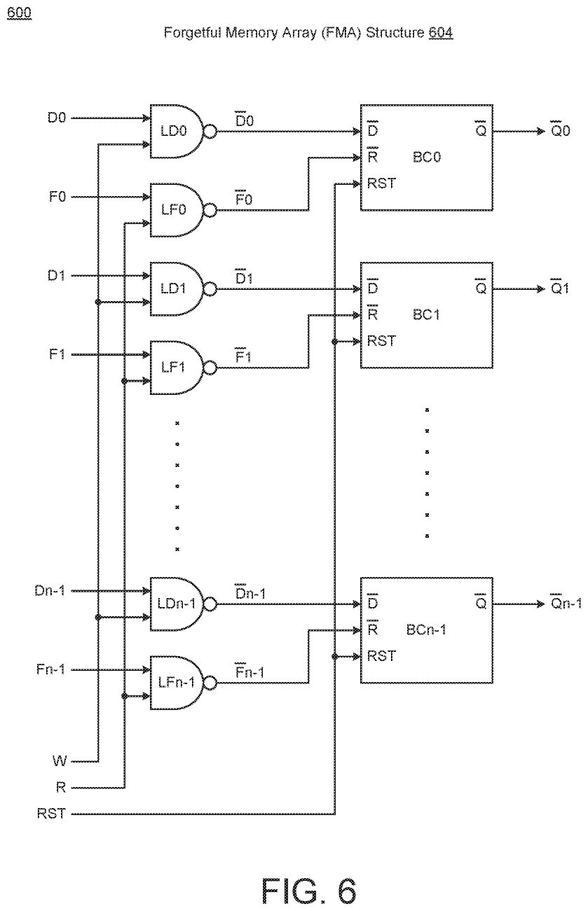

FIG. 6 illustrates a diagram 600 of a forgetful memory array (FMA) structure 604 in accordance with various implementations described herein.

In various implementations, the FMA structure 604 may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the FMA structure 604 as an integrated device may involve the use of various circuit components and/or related structures described herein so as to implement various techniques associated therewith. Also, the FMA structure 604 may be integrated with various circuitry and/or related components on a single chip, and also, the FMA structure 604 may be implemented in various embedded devices for use in automotive, mobile, computer, server and/or Internet-of-Things (IoT) based applications, including various circuits related thereto, such as, e.g., remote sensor nodes.

As shown in FIG. 6, the forgetful memory array (FMA) structure 604 may be implemented as a forgetful bloom filter having an array of leaky bitcells (BC0, BC1, . . . , BCn−1) with each leaky bitcell having at least one capacitive element, such as at least one capacitor (C), in a manner as shown in FIG. 5B. As such, the forgetful memory array (FMA) structure 604 may be implemented as a forgetful bloom filter with the one or more leaky bitcells as forgetful memory cells comprising capacitive elements (C) that gradually discharge over a period of time. Also, FMA structure 604 may include one or more inputs, such as, e.g., input data (D0, D1, . . . , Dn−1), function data (F0, F1, . . . , Fn−1), write enable input (W), refresh input (R), and reset input (RST), along with output data (Q0, Q1, . . . , Qn−1). In some applications, the output data (Q0, Q1, . . . , Qn−1) may refer to inverted output data (Q0-not, Q1-not, . . . , Qn−1-not).

In some implementations, the FMA structure 604 may include data logic gates, such as, e.g., NAND logic gates (LD0, LD1, LDn−1), that receive the input data (D0, D1, . . . , Dn−1), receive the write enable input (W), and then provide inverted input data (D0-not, D1-not, . . . , Dn−1-not) to data inputs (D-not) of corresponding leaky bitcells (BC0, BC1, . . . , BCn−1). For instance, as shown, each NAND logic gate (LD0, LD1, LDn−1) receives corresponding input data (D0, D1, . . . , Dn−1), receives the write enable input (W), and then provides corresponding inverted input data (D0-not, D1-not, . . . , Dn−1-not) to corresponding leaky bitcells (BC0, BC1, . . . , BCn−1) in the FMA structure 604.

In some implementations, the FMA structure 604 may have function logic gates, such as, e.g., NAND logic gates (LF0, LF1, LFn−1), that receive the function data (F0, F1, . . . , Fn−1), receive the refresh input (R), and then provide inverted function data (F0-not, F1-not, . . . , Fn−1-not) to refresh inputs (R-not) of corresponding leaky bitcells (BC0, BC1, . . . , BCn−1). For instance, as shown, each NAND logic gate (LF0, LF1, LFn−1) receives corresponding function data (F0, F1, . . . , Fn−1), receives the refresh input (R), and then provides corresponding inverted function data (F0-not, F1-not, . . . , Fn−1-not) to the corresponding leaky bitcells (BC0, BC1, . . . , BCn−1) in the FMA structure 604.

Also, in some implementations, as shown in FIG. 6, each corresponding leaky bitcell (BC0, BC1, . . . , BCn−1) receives corresponding inverted input data (D0-not, D1-not, . . . , Dn−1-not) at data input (D-not), receives corresponding inverted function data (F0-not, F1-not, . . . , Fn−1-not) at refresh input (R-not), receives the reset input (RST), and then provides corresponding inverted output data (Q0-not, Q1-not, . . . , Qn−1-not), as an output from the FMA structure 604.

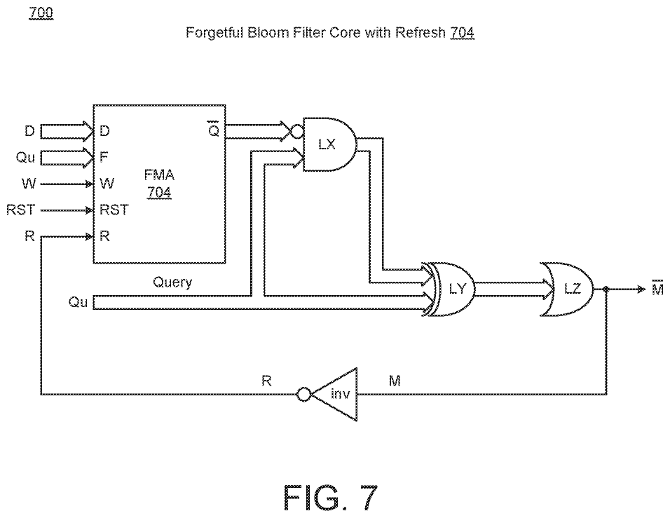

FIG. 7 illustrates a diagram 700 of a forgetful bloom filter core 704 with refresh in accordance with various implementations described herein.

In various implementations, the forgetful bloom filter core 704 may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the forgetful bloom filter core 704 as an integrated device may involve use of various circuit components and/or related structures described herein so as to implement various techniques associated therewith. Also, the forgetful bloom filter core 704 may be integrated with various circuitry and/or related components on a single chip, and the forgetful bloom filter core 704 may be implemented in various embedded devices for use in automotive, mobile, computer, server and/or IoT based applications, including, e.g., remote sensor nodes.

As shown in FIG. 7, the forgetful bloom filter core 704 may be implemented with the forgetful memory array (FMA) structure 604 in FIG. 6 having the array of leaky bitcells (BC0, BC1, . . . , BCn−1), wherein each leaky bitcell has at least one capacitive element, such as at least one capacitor (C), in a manner as shown in FIG. 5B. As such, the forgetful bloom filter core 704 may be implemented as a forgetful bloom filter with the array of leaky bitcells as an array of forgetful memory cells comprising capacitive elements (C) that gradually discharge over a period of time. Also, the forgetful bloom filter core 704 may include one or more inputs, such as, e.g., input data (D: D0, D1, . . . , Dn−1), function data (F: F0, F1, . . . , Fn−1), write enable input (W), reset input (RST), and refresh input (R) along with the output data (Q-not: Q0-not, Q1-not, . . . , Qn−1-not).

In some implementations, the forgetful bloom filter core 704 may include multi-input logic gates, such as, e.g., AND gate (LX), XOR gate (LY), and OR gate (LZ). For instance, the AND gate (LX) may receive the output data (Q-not: Q0-not, Q1-not, . . . , Qn−1-not) at an inverting input, receive a query input (Qu) at a non-inverting input, and provide output to the XOR gate (LY). Also, the XOR gate (LY) may receive the output from the AND gate (LX), receive the query input (Qu), and provide output to the OR gate (LZ). Also, the OR gate (LZ) may receive the output from the XOR gate (LY), and provide a match output (M-not) as output from the forgetful bloom filter core 704. In some applications, the logic gates (LX, LY, LZ) refer to a query circuit that identifies matches between a query data (input Qu) and the output data (Q-not: Q0-not, Q1-not, . . . , Qn−1-not) provided by the read element(s) or the read circuit stage(s) of the forgetful bloom filter core 704.

In some applications, upon receiving the query input (Qu), the query circuit (LX, LY, LZ) may invert data bits of the output data (Q-not) and then mask the inverted data bits of the output data (Q-not) so as to isolate the inverted data bits of the output data (Q-not) having a high logic state. After isolating the inverted data bits, the query circuit (LX, Ly, LZ) may XOR (e.g., with LY) the masked inverted data bits with data bits of the query input (Qu) to generate queried output data. If there is a match between data bits of stored input data and data bits of the queried output data, then the query circuit (LX, LY, LZ) may assert a match signal (M-not). Otherwise, if there is a mismatch between the data bits of the stored input data and the data bits of the queried output data, then the query circuit (LX, LY, LZ) may be configured to assert a mismatch signal with the M signal.

Also, in some applications, the match output signal (M-not) may be provided to the refresh input (R) of the FMA structure 704 by way of inverter (inv). For instance, the match output signal (M-not) is provided to the input of inverter (inv), which then provides the refresh signal (R) as a feedback signal to the refresh input (R) of the FMA structure 704.

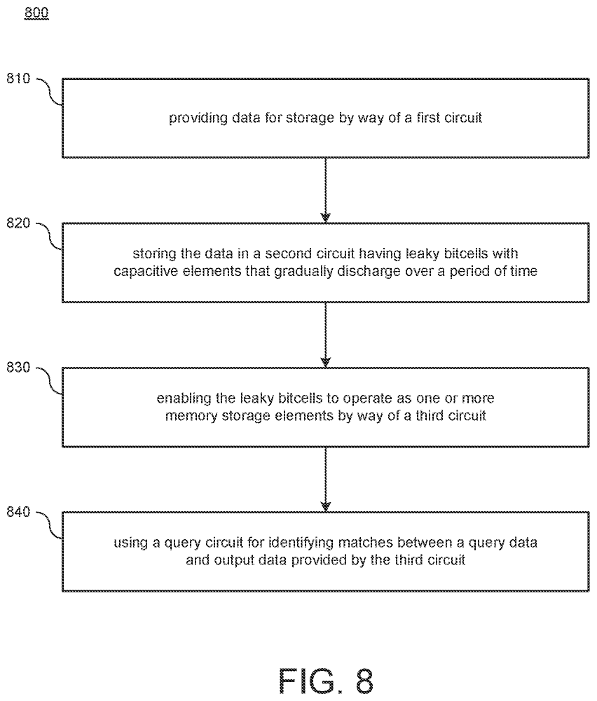

FIG. 8 illustrates a diagram of a method 800 for using a bitcell structure in the various configurations in accordance with various implementations described herein.

It should be understood that even though the method 800 indicates a particular order of operation execution, in some instances, various certain portions of the operations may be executed in a different order, and on different systems. In other cases, additional operations and/or steps may be added to and/or omitted from method 800. Also, method 800 may be implemented in hardware and/or software. If implemented in hardware, the method 800 may be implemented with various components and/or circuitry, as described in FIGS. 1A-7. Also, if implemented in software, method 800 may be implemented with program and/or software instruction processes configured for providing forgetful bloom filter schemes, techniques and applications, as described herein. Also, if implemented in software, instructions related to implementing method 800 may be stored in memory, such as a database. Also, in various instances, a computer or other types of computing devices having a processor and memory may be configured to perform method 800.

In various implementations, method 800 may refer to a method for designing, providing, fabricating and/or manufacturing forgetful bloom filter schemes and techniques as an integrated system, device and/or circuit that involves use of circuit components and related structures described herein so as to implement various schemes and techniques associated therewith. Also, various forgetful bloom filter schemes and techniques may be integrated with computing circuitry and related components on a single chip, and the forgetful bloom filter schemes and techniques may be implemented in embedded systems for various electronic, mobile and IoT applications, including remote sensor nodes.

At block 810, method 800 may provide data for storage by way of a first circuit, such as, e.g., the write element or write circuit stage, as shown in FIGS. 1B and 5B. As such, in some applications, the first circuit may comprise a write circuit, and the data may be provided to a second circuit, such as, e.g., a memory circuit for storage by way of the write circuit. At block 820, method 800 may store the data in a second circuit having leaky bitcells with capacitive elements that gradually discharge over a period of time, such as, e.g., the memory element or memory circuit stage, as shown in FIGS. 1B and 5B. Thus, in some applications, the second circuit may comprise a memory circuit, and the data may be stored in the memory circuit with the leaky bitcells comprising the capacitive elements (e.g., capacitors) that gradually discharge over the period of time. Also, each capacitive element may be referenced to a supply voltage (VDD) or ground (VSS or GND) such that each capacitive element slowly leaks (or decays, or discharges) so that each leaky bitcell is configured to forget its data storage value over the period of time.

At block 830, method 800 may enable the leaky bitcells to operate as one or more memory storage elements by way of a third circuit, such as, e.g., the read element or read circuit stage, as shown in FIGS. 1B and 5B. As such, in some applications, the third circuit may comprise a non-destructive read circuit that enables each leaky bitcell to operate as a non-destructive memory storage element without destructive read operations that cause a refresh operation. Further, at block 840, method 800 may use a query circuit for identifying matches between a query data and output data provided by the third circuit, such as, e.g., the read element or read circuit stage, as shown in FIGS. 3-4 and 7. Also, in various applications, the method may be performed by a forgetful bloom filter with the one or more leaky bitcells as forgetful memory cells comprising the capacitive elements that gradually discharge over the period of time.

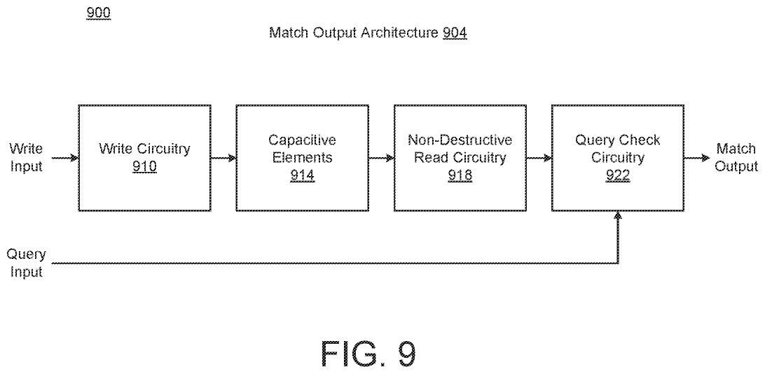

FIG. 9 illustrates a high-level diagram 900 of match output architecture 904 in accordance with various implementations described herein.

In various implementations, the match output architecture 904 may provide for fabricating forgetful memory circuitry with various integrated circuit (IC) components that may be arranged and/or coupled together as an assemblage or some combination of parts that provide for physical circuit designs, structures and applications. In various instances, a method of designing, providing and fabricating the match output architecture 904 as an integrated device may involve use of various circuit components and/or related structures described herein so as to implement various techniques associated therewith. Also, the match output architecture 904 may be integrated with circuitry and/or related components on a single chip, and the match output architecture 904 may be implemented in various embedded devices for use and application in automotive, mobile, computer, server and/or IoT based applications, including, e.g., remote sensor nodes.

As shown in FIG. 9, the match output architecture 904 may be implemented as a forgetful memory device having leaky bitcells with capacitive elements, such as, e.g., capacitors (C). Also, the match output architecture 904 may use one or more inputs, such as, e.g., a write input and a query input, and also, the match output architecture 904 may provide at least one output, such as, e.g., a match output, based on the write input and/or the query input, in various operational applications.

As shown in FIG. 9, the match output architecture 904 may include multiple circuits or stages with various elements, including write circuitry 910, memory circuitry 914 with capacitive elements (e.g., capacitors), non-destructive read circuitry 918, and query check circuitry 922, that are arranged and coupled together so as to thereby operate as a forgetful memory device having leaky bitcells with the capacitive elements.

In some implementations, the write circuitry 910 may refer to a write element or write circuit stage that provides write data from the write input to the memory circuitry 914 for storage in the capacitive elements of the leaky bitcells. Also, in some implementations, the memory circuitry 914 may refer to a memory element or a memory circuit stage that stores the write data received from the write circuitry 910 in capacitive elements, such as, e.g., capacitors, that gradually discharge over a pre-determined period of time.

In some implementations, the non-destructive read circuitry 918 may refer to a read element or a read circuit stage that enables the leaky bitcells to operate as memory storage elements. In some applications, the read element may refer to a non-destructive read element having the leaky bitcell. Also, in some instances, the read circuitry 918 may include Schmitt trigger circuitry. Thus, the read circuitry 918 may be implemented as non-destructive read circuitry so as to enable the leaky bitcells to operate as non-destructive memory storage elements without destructive read operations that may cause a refresh operation. However, in some other applications, the read element may be implemented as a destructive read element, in manner as described herein below in reference to bitcell structure 1104 in FIG. 11. Thus, in various applications, the read circuitry 918 may refer to non-destructive read circuitry or destructive read circuitry.

In some implementations, the query circuitry 922 may refer to a query element or query circuit stage that identifies matches between query data from the query input and the output data provided by the non-destructive read circuitry 918. Also, the query circuitry 922 may receive the query input and then identify matches between the query data in the query input and the output data of the match output provided by the non-destructive read circuitry 918. Also, in some instances, upon receiving the query input, the query circuitry 922 may identify one or more matches between data bits of the stored input data and data bits of the output data having a high logic state. Also, in response to a identifying a match, one or more bits representative of the output data identified by the match are written back into the leaky bitcells, which may be implemented as a refresh operation.

In some implementations, upon receiving the query input, the query circuitry 922 may be configured to invert data bits of the output data and then mask the inverted data bits of the output data so as to isolate the inverted data bits of the output data having a high logic state. Also, after isolating the inverted data bits, the query circuitry 922 may perform a logic operation (e.g., XOR operation) on the masked inverted data bits with data bits of the query input to generate queried output data, such as, e.g., in the form of the match output. In some applications, if there is a match between the data bits of the stored input data and data bits of the queried output data, then the query circuitry 922 asserts a match signal. Otherwise, in other applications, if there is a mismatch between data bits of the stored input data and the data bits of the queried output data, then the query circuitry 922 may be configured to assert a mismatch signal.

FIGS. 10A-10C illustrate various diagrams associated with a bitcell structure in a third configuration in accordance with various implementations as described herein.

In particular, FIG. 10A shows a diagram 1000A of a bitcell structure 1004A in the third configuration, FIG. 10B shows a transistor-level diagram 1000B of a bitcell structure 1004B in the third configuration, and FIG. 10C shows an operational waveform diagram 1000C for the bitcell structure 1004C in the third configuration.

In various implementations, the bitcell architecture may provide for fabricating memory circuitry with various integrated circuit (IC) components that may be arranged and/or coupled together as an assemblage or some combination of parts that provide for physical circuit designs, structures and/or applications. In various instances, a method of designing, providing and fabricating the bitcell architecture as an integrated device may involve the use of various circuit components and/or related structures described herein so as to implement various techniques associated therewith. Also, the bitcell architecture may be integrated with various circuitry and/or related components on a single chip, and also, the bitcell architecture may be implemented in various embedded devices for use in automotive, mobile, computer, server and/or Internet-of-Things (IoT) based applications, including various circuits related thereto, such as, e.g., remote sensor nodes.

As shown in FIG. 10A, the bitcell architecture 1004A may be implemented as a forgetful memory device having a leaky bitcell (BC) with at least one capacitive element, such as, e.g., a capacitor (C). Also, the bitcell architecture 1004A may have one or more inputs, such as, e.g., input data (D) and reset (RST), and an output, such as, e.g., output data (Q). In some instances, the reset (RST) may refer to inverted reset (RST-not).

As shown in FIG. 10B, the bitcell architecture 1004B may include multiple stages, including a first stage (Stage_1), a second stage (Stage_2), and a third stage (Stage_3), that are arranged and coupled together in a third configuration so as to thereby operate as a forgetful memory device (e.g., as shown in FIG. 10A) having a leaky bitcell (BC) with at least one capacitive element, such as, e.g., a capacitor (C).

In some implementations, the first stage (Stage_1) may refer to a write element or write circuit stage of the leaky bitcell, wherein the write circuit stage (Stage_1) provides data for storage in the second stage (Stage_2). Also, in some applications, the first stage (Stage_1) may include one or more transistors, such as, e.g., transistors (T1, T2) coupled together in series between a supply voltage (VDD) and ground (VSS or GND). As shown, transistor (T1) is coupled between the supply voltage (VDD) and node (n1), and transistor (T2) is coupled between node (n1) and ground (VSS or GND). Also, the input reset (RST-not) is coupled to the gate of transistor (T1), and the input data (D) is coupled to the gate of transistor (T2). Also, transistor (T1) may be a P-type transistor, and transistor (T2) may be an N-type transistor; however, other configurations may be used.

In some implementations, the second stage (Stage_2) may refer to a memory element or memory circuit stage of the leaky bitcell, wherein the memory circuit stage (Stage_2) stores the data received from the first stage (Stage_1) in at least one capacitive element, such as, e.g., the capacitor (C), that gradually discharges over a pre-determined period of time. Also, in various applications, the capacitor (C) may have a decay time that is determined by the size of the capacitor (C), self-leakage current of the capacitor (C), and/or leakage current of connected transistors, such as, e.g., one or more of transistors (T1, T2, T5). As such, the leaky bitcell may be referred to as a capacitive bitcell having the capacitive element, such as, e.g., the capacitor (C), that gradually discharges over the period of time by slowly leaking stored charge over the period of time. Also, the capacitor (C) may be coupled between supply voltage (VDD) and node (n1) or node (Vc), wherein node (Vc) refers to the voltage potential of the capacitor (C) at node (n1).

In some instances, the capacitive element or capacitor (C) may be referenced to supply voltage (VDD) such that the capacitive element or capacitor (C) slowly leaks to the supply voltage (VDD) so that the leaky bitcell is configured to forget its data storage value over the period of time. Also, in other instances, as shown in FIGS. 1B and 5B, the capacitive element or capacitor (C) may be referenced to ground (VSS or GND) such that the capacitive element or capacitor (C) slowly leaks to ground (VSS or GND) so that the leaky bitcell is configured to forget its data storage value over the period of time. Thus, in various instances, the leaky bitcell may be provided with a capacitive storage element that is supply-voltage-referenced (VDD), which corresponds to a positive voltage supply (VDD), or that may be ground-referenced (VSS or GND).

In some implementations, the third stage (Stage_3) may refer to a read element or a read circuit stage of the leaky bitcell, wherein the read circuit stage (Stage_3) enables the leaky bitcell to operate as one or more memory storage elements. In some instances, the read element may refer to a non-destructive read element of the leaky bitcell, wherein the non-destructive read circuit enables the leaky bitcell to operate as a non-destructive memory storage element without need for destructive read operations that cause a refresh operation. Moreover, in some other instances, the read element may refer to a destructive read element, as described in reference to the bitcell structure 1104 in FIG. 11.

Also, in some applications, the third stage (Stage_3) may include one or more transistors, such as, e.g., transistor (T5) that is coupled between the output node (Q-not) and ground (VSS or GND). As shown, the output of transistor (T1) is coupled to the gate of transistor (T5) at node (n1), and also, the input of transistor (T5) is coupled to the output node (Q-not). In some instances, transistor (T5) may be an N-type transistor; however, in other instances, other configurations may be used to achieve similar results.

As shown in FIG. 10C, operational waveform diagram 1000C for the bitcell structure 1004A, 1004B in the third configuration shows the input data signal (D), the Vc signal at node (n1), the output data signal (Q), and the reset signal (RST-not). As shown, in time period (t0-t1), during activation of reset signal (RST-not) high, the input data signal (D) is low, the Vc signal at node (n1) is low, and the output data signal (Q) is high.

Also, in time period (t1-t2), when the reset signal (RST-not) toggles from low to high, the input data signal (D) remains low, the Vc signal inverts from low to high, and the output signal (Q) inverts from high to low.

Also, in time period (t2-t3), the input data signal (D) triggers the Vc signal at node (n1) from high to low, and the output signal (Q) inverts high, when reset signal (RST-not) is set high, wherein the Vc signal slowly charges high to time (t4). As such, when the input data signal (D) toggles high, the Vc signal triggers low followed by slow charge high, and the output signal (Q) is high during time (t2-t3). Also, in time period (t3-t4), data signal (D) remains low, and Vc signal continues to charge high to time (t4), and the output signal (Q) inverts from high to low, while the reset signal (RST-not) remains high.

Also, in time period (t4-t5), the input data signal (D) triggers the Vc signal low at node (n1), and the output signal (Q) inverts from low to high at time (t4), while the reset signal (RST-NOT) remains high, wherein the Vc signal slowly charges to time (t5). Also, in time period (t5-t6), the input data signal (D) remains low, while the Vc signal at node (n1) continues to charge to time (t6), and the output signal (Q) remains high during the charge of the Vc signal to time (t6).

Also, in time period (t6-t7), the input data signal (D) triggers the Vc signal low at node (n1), and the output signal (Q) remains high to time (t7), while the reset signal (RST-not) remains high, wherein the Vc signal slowly charges to time (t8). Also, in time period (t7-t8), input data signal (D) remains low, while the Vc signal at node (n1) continues to charge to time (t8), and the output signal (Q) inverts from high to low at time (t7) during the charge of the Vc signal to time (t8).

FIG. 11 illustrates a diagram 1100 of a destructive read bitcell structure 1104 in accordance with various implementations described herein.

In some implementations, the bitcell structure 1104 may provide for fabricating memory circuitry with various integrated circuit (IC) components that are arranged and/or coupled together as an assemblage or some combination of parts that provide for physical circuit designs, structures and/or applications. In some instances, a method of designing, providing and fabricating the bitcell structure 1104 as an integrated device may involve the use of various circuit components and/or related structures described herein so as to implement various techniques associated therewith. Also, the bitcell structure 1104 may be integrated with various circuitry and/or related components on a single chip, and also, the bitcell structure 1104 may be implemented in various embedded devices for use in automotive, mobile, computer, server and/or Internet-of-Things (IoT) based applications, including various circuits related thereto, such as, e.g., remote sensor nodes.

As shown in FIG. 11, the bitcell structure 1104 may be implemented, e.g., as a destructive read bitcell structure having at least one capacitive element, such as, e.g., a capacitor (C). Also, the bitcell structure 1104 may include one or more inputs, such as, e.g., input data (D), write enable (W), and refresh (R), along with at least one output, such as, e.g., output data (Q). Also, the bitcell structure 1104 may include transistors (T6, T7), wherein transistor (T6) is coupled between the input data (D) and an input of buffer (B1) at node (nB), which is coupled between transistor (T6) and the output (Q). Also, transistor (T7) may be coupled in series with the capacitor (C) between node (nB) and ground (VSS or GND). Also, the write enable (W) may be coupled to the gate of transistor (T6). Also, the bitcell structure 1104 may include a logic gate (LWR), such as, e.g., an OR gate, that receives the write enable (W), receives the refresh signal (R), and then provides an output signal to the gate of transistor (T7).

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

Described herein are various implementations of a device having a write circuit that provides data for storage. The device may include a memory circuit that stores the data in leaky bitcells with capacitive elements that gradually discharge over a pre-determined period of time. The device may include a read circuit that enables the leaky bitcells to operate as one or more memory storage elements. The device may include a query circuit that identifies matches between a query data and output data provided by the read circuit.

Described herein are various implementations of a method. The method may provide data for storage by way of a first circuit. The method may store the data in a second circuit having leaky bitcells with capacitive elements that gradually discharge over a period of time. The method may enable the leaky bitcells to operate as one or more memory storage elements by way of a third circuit. The method may use a query circuit to identify matches between a query data and output data provided by the third circuit.

Described herein are various implementations of a device with a memory circuit that stores input data in leaky bitcells with capacitive elements that gradually discharge over a period of time. The device may include a read circuit that enables the leaky bitcells to operate as one or more memory storage elements. Also, the device may further include a query circuit that identifies matches between query data and output data provided by the read circuit.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. Also, the terms “includes,” “including,” “comprises,” and/or “comprising,” when used in this specification, may specify a presence of stated features, integers, steps, operations, elements, and/or components, but do not preclude presence or addition of one or more other various features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A device comprising:
a write circuit that provides data for storage;
a memory circuit that stores the data in leaky bitcells with capacitive elements that gradually discharge over a pre-determined period of time;
a read circuit that enables the leaky bitcells to operate as one or more memory storage elements; and
a query circuit that identifies matches between a query data and output data provided by the read circuit.

2. The device of claim 1, wherein the read circuit is a non-destructive read circuit or destructive read circuit.

3. The device of claim 1, wherein each capacitive element is referenced to a supply voltage or a ground voltage such that each capacitive element slowly leaks so that each leaky bitcell is configured to forget its data storage value over the period of time.

4. The device of claim 1, wherein the read circuit is a non-destructive read circuit that enables the leaky bitcells to operate as non-destructive memory storage elements without destructive read operations that cause a refresh operation.

5. The device of claim 1, wherein the device is a forgetful bloom filter having the one or more leaky bitcells as forgetful memory cells comprising the capacitive elements that gradually discharge over the period of time.

6. A method comprising:
providing data for storage by way of a first circuit;
storing the data in a second circuit having leaky bitcells with capacitive elements that gradually discharge over a period of time;
enabling the leaky bitcells to operate as one or more memory storage elements by way of a third circuit; and
using a query circuit for identifying matches between a query data and output data provided by the third circuit.

7. The method of claim 6, wherein the first circuit comprises a write circuit, wherein the data is provided to the memory circuit for storage by way of the write circuit.

8. The method of claim 6, wherein the second circuit comprises a memory circuit, and wherein the data is stored in the memory circuit having the leaky bitcells comprising the capacitive elements that gradually discharge over the period of time.

9. The method of claim 6, wherein each capacitive element is referenced to a supply voltage or ground such that each capacitive element slowly leaks so that each leaky bitcell is configured to forget its data storage value over the period of time.

10. The method of claim 6, wherein the third circuit comprises a non-destructive read circuit that enables each leaky bitcell to operate as a non-destructive memory storage element without destructive read operations that cause a refresh operation.

11. The method of claim 6, wherein the method is performed by a forgetful bloom filter having the one or more leaky bitcells as forgetful memory cells comprising the capacitive elements that gradually discharge over the period of time.

12. A device comprising:
a memory circuit that stores input data in leaky bitcells with capacitive elements that gradually discharge over a period of time;
a read circuit that enables the leaky bitcells to operate as one or more memory storage elements; and
a query circuit that identifies matches between query data and output data provided by the read circuit.

13. The device of claim 12, further comprising:
a write circuit that provides the data to the memory circuit for storage.

14. The device of claim 12, wherein the read circuit is a non-destructive read circuit or a destructive read circuit.

15. The device of claim 12, further comprising:
one or more hash functions that are configured to either write or query data bits in the leaky bitcells.

16. The device of claim 12, wherein the read circuit is a non-destructive read circuit that enables each leaky bitcell to operate as a non-destructive memory storage element without destructive read operations that cause a refresh operation.

17. The device of claim 12, wherein the read circuit comprises a Schmitt trigger circuit.

18. The device of claim 12, wherein:
the query circuit receives a query input and then identifies matches between the query data and the output data provided by the read circuit, and
upon receiving the query input, the query circuit identifies matches between data bits of the stored input data and data bits of the output data having a high logic state.

19. The device of claim 18, wherein in response to a match being identified, one or more bits representative of the output data identified by the match are written back into the leaky bitcells.

20. The device of claim 18, wherein:
upon receiving the query input, the query circuit inverts data bits of the output data and then masks the inverted data bits of the output data so as to isolate the inverted data bits of the output data having a high logic state,
after isolating the inverted data bits, the query circuit XORs the masked inverted data bits with data bits of the query input to generate queried output data,
if there is a match between the data bits of the stored input data and the data bits of the queried output data, then the query circuit asserts a match signal, and
if there is a mismatch between the data bits of the stored input data and the data bits of the queried output data, then the query circuit asserts a mismatch signal.
